(19) United States
(12) Patent Application Publication
(10) Pub. No.: US 2021/0210403 A1
(43) Pub. Date: Jul. 8, 2021

(54) HEAT SPREADING PLATE HAVING ATLEAST ONE COOLING FIN METHOD FOR PRODUCING A HEAT SPREADING PLATE HAVING ATLEAST ONE COOLING FIN ELECTRONIC MODULE

(71) Applicant: Heraeus Deutschland GmbH & Co. KG, Hanau (DE)

(72) Inventor: Ronald EISELE, Surendorf (DE)

(73) Assignee: Heraeus Deutschland GmbH & CO., KG, Hanau (DE)

(21) Appl. No.: 15/999,720

(22) PCT Filed: Feb. 9, 2017
(86) PCT No.: PCT/EP2017/052872

§ 371 Date: Aug. 20, 2018

(30) Foreign Application Priority Data
Feb. 19, 2016 (EP) 16156492.7

(51) Int. Cl. H01L 23/367; H01L 23/373; H01L 23/473; H01L 21/48

(52) U.S. Cl. CPC H01L 23/3672; H01L 21/4878; H01L 23/473; H01L 23/3735

(57) ABSTRACT

One aspect relates to a heat spreading plate having at least one cooling fin. The heat spreading plate includes at least a first layer and at least a second layer, and at least one surface portion bent out of a base surface of the second layer forms a cooling fin.

The invention relates to a heat spreading plate having at least one cooling fin. The invention also relates to a method for producing a heat spreading plate with at least a first layer and at least a second layer and at least one cooling fin. Moreover, the invention relates to an electronic module with at least one electronic component and at least one heat spreading plate.

Power-electronic semiconductors and their circuit carriers must open thermal pathways to the surroundings in order to dissipate the heat of the power losses. The mentioned subassemblies are typically arranged with their circuit carriers on heat-conducting plates made of copper. In order to cool the power-electronic semiconductors and their circuit carriers, it is known to carry out cooling with the aid of liquids and/or gases. For this purpose, cooling fins are formed on the heat-conducting plates or on heat spreading plates. Such cooling fins typically project above the base surface of the heat-conducting plate or heat spreading plate. The degree of heat dissipation that can be achieved by the cooling fins essentially depends on the surface enlargement that these cooling fins achieve compared to the flat base surface.

The surface enlargement or the creation of cooling fins takes place for example by milling from a solid plate or with the aid of various casting techniques. It is also known to produce the shape of the cooling fins by hot or cold extrusion or additive techniques such as welding or soldering.

Generally, the production of heat spreading plates by means of shaping production processes is technologically time-consuming and costly. In the production of cooling fins by milling the same from a solid plate, an extremely large amount of material is consumed by this subtractive production technique. Copper casting, which is produced in particular with sand moulds, generates less material consumption, but rejects are generated with this production method on account of high shape tolerances. On account of the coarse material surface, moreover, a final surface smoothing step is often additionally required.

The production of heat spreading plates or heat-conducting plates with cooling fins on the basis of a powder-based metal injection-moulding process is also known. Such a process, however, is time-consuming and costly on account of the large number of process steps.

Proceeding from this prior art, it is the problem of the present invention to specify a further-developed heat spreading plate with at least one cooling fin, which can be produced in an extremely straightforward and cost-effective manner and is constituted advantageously with regard to a surface enlargement.

Furthermore, it is a problem of the present invention to specify a method for producing a heat spreading plate, wherein the method can be carried out in a straightforward and cost-effective manner and a considerable surface enlargement can be achieved without additional material consumption.

Moreover, it is a problem of the present invention to specify an electronic module with at least one electronic component and a heat spreading plate according to the invention or a heat spreading plate produced according to the invention.

According to the invention, the problem with regard to the heat spreading plate with at least one cooling fin is solved by the subject-matter of claim 1, with regard to the method of producing a heat spreading plate with at least a first layer and at least a second layer and at least one cooling fin by the subject-matter of claim 8, and with regard to the electronic module with at least one electronic component and at least one heat spreading plate by the subject-matter of claim 14.

The invention is based on the idea of specifying a heat spreading plate with at least one cooling fin, wherein the heat spreading plate according to the invention comprises at least a first layer and at least a second layer, wherein at least one surface portion which is bent out from a base surface of the second layer forms a cooling fin.

The heat spreading plate can also be referred to as a heat-conducting plate or heat sink plate.

According to the invention, the heat spreading plate comprises at least two layers, wherein the at least second layer comprises at least one surface portion bent out from the base surface, wherein this surface portion forms a cooling fin.

A bent-out surface portion is understood to mean any surface portion which has a different orientation with regard to the base surface and comprises at least in sections a bending portion. In other words, the bent-out surface portion can also be folded out and/or pressed out and/or pushed out, wherein these surface portions also comprise a bending portion at least in sections.

The second layer is constituted monolithic, i.e. in one piece, with the at least one bent-out surface portion. The bent-out surface portion is connected to the base surface. This connecting portion can be the bending portion of the surface portion. A surface-enlarging portion can adjoin the bending portion. In other words, the surface-enlarging portion of the cooling fin is connected by means of a bending portion to the base surface.

The first layer and/or the at least second layer is or are preferably formed from a heat-conducting material. Preferably, both the first layer and also the at least second layer are formed from heat-conducting material. In a preferred embodiment of the invention, the first layer and/or the at least second layer is or are formed from copper and/or a copper alloy and/or aluminium and/or an aluminium alloy and/or aluminium silicon carbide (AlSiC).

A connection layer, in particular a sintered layer or bonding layer or solder layer, can be constituted between the first layer and the second layer.

The connecting material is preferably introduced as a sintered material or a component of a sintered material between the at least first layer and the at least second layer. A composition that can be sintered to form a conductive layer can accordingly be used to produce a sintered connection between the layers to be connected. The still sinterable composition can have the form of application of an ink, a paste or a sintered preform in the form of a layer-shaped pressing. Sintered preforms arise by the application and drying of metallic pastes or metallic sintering pastes. Such sintered preforms are still sinterable.

Alternatively, it is possible for the connecting material to be constituted as foil, in particular as metal foil, and for this foil, in particular metal foil, to be arranged between the first layer and the second layer.

It is possible for the sintering paste to be applied by printing, in particular screen printing or stencil printing, on the first layer and/or the second layer. Optionally, the sintering paste or metal sintering paste can be dried before the actual sintering process is carried out. Without passing through the liquid state, the metal particles of the sintering paste are joined together during the sintering by diffusion thereby forming a firm, electrical current-conducting and heat-conducting metallic connection or metal connection between the at least first and at least second layer. For the connection of the at least first and at least second layer, a sintering paste is particularly preferably used which comprises silver and/or a silver alloy and/or silver carbonate and/or silver oxide.

Moreover, it is possible to use a sintering paste which comprises gold (Au) and/or a gold alloy and/or copper (Cu) and/or a copper alloy.

In a further embodiment of the invention, a third layer made of a low-expansion material can be constituted between the first layer and the second layer. The low-expansion material can be a nickel alloy, in particular invar (Fe₆₅Ni₃₅) or invar 36 (Fe₆₄Ni₃₆) or kovar (Fe₅₄Ni₂₉Co₁₇), and/or tungsten (W) and/or iron-nickel-cobalt alloy (FeNiCo alloy). With regard to the low-expansion material of the third layer, molybdenum (Mo) or a molybdenum alloy has proved to be a particularly preferred material. The third layer can thus be made of molybdenum or a molybdenum alloy or comprise molybdenum or a molybdenum alloy.

The third layer made of a low-expansion material brings about a reduction in expansion with rising temperature and thus reduces the expansion difference with respect to materials of an electronic subassembly, which is connected or can be connected to the heat spreading plate. On account of the third layer made of a low-expansion material, it is possible to prevent stress-induced cracks arising in a jointing zone between an electronic subassembly and the heat spreading plate and the heat flow from being significantly impeded due to the cracks. This is particularly advantageous when the electronic subassembly to be connected or the connected electronic subassembly comprises a second carrier, which has a lower thermal expansion than the first layer and/or the second layer of the heat spreading plate.

The at least one cooling fin can be constituted pin-shaped or rectangular or semicircular or square. This is not an exhaustive list of geometrical figures. Other shapes of the at least one cooling fin are also possible. For example, the at least one cooling fin can be constituted polygonal, in particular triangular or pentagonal.

Insofar as the heat spreading plate comprises a plurality of cooling fins, it is possible for the cooling fins to have different shapes.

A/the bent-out surface portion can be arranged at an angle of 10°-90° to the base surface of the second layer. In particular, the surface-enlarging portion of the bent-out surface portion can be formed at an angle of 10°-90° to the base surface. A/the bent-out surface portion is preferably constituted perpendicular to the base surface of the second layer.

Insofar as the heat spreading plate comprises a plurality of cooling fins, the cooling fins, in particular the bent-out surface portions, preferably have the same angle at which the latter are arranged with respect to the base surface of the second layer.

Insofar as a plurality of cooling fins, which are formed as surface portions bent out from the base surface, are constituted, it is advantageous if these cooling fins are arranged at the same distance from one another.

The surface of the heat spreading plate can comprise at least in sections a corrosion-inhibiting coating, in particular a galvanic nickel coating. The surface of the heat spreading plate is understood to mean both the surface of the first layer and also the surface of the second layer. The surface of the heat spreading plate also includes the cooling fins. The second side of the first layer facing the second layer can also form at least in sections the surface of the heat spreading plate. This second side of the first layer is exposed in the portions in which the surface portions bent out of the second layer are formed from the base surface.

The complete surface of the heat spreading plate is preferably provided with a corrosion-inhibiting coating. The corrosion-inhibiting coating can be a twofold, galvanic nickel coating. A corrosion-inhibiting coating of the surface of the heat spreading plate is primarily advantageous when the heat spreading plate is used in connection with water cooling or liquid cooling.

Alternatively, it is possible for only the second layer or the second side of the second layer and the cooling fin(s) to have a nickel coating. In addition, the exposed portions of the second side of the first layer can have a coating. These portions of the heat spreading plate in particular are exposed to water or a liquid in the state when in use.

With the aid of the heat spreading plate according to the invention, a heat spreading plate with at least one cooling fin is made available, which is advantageously formed with regard to the surface enlargement, wherein the surface enlargement is created without additional material consumption. The share of the thermal resistance falls proportionately with the surface enlargement. The heat spreading plate preferably comprises a plurality of cooling fins.

The surface enlargement or the surface growth with regard to a cooling fin, i.e. with regard to a bent-out surface portion, is composed of four surface components. The first surface component is the rear side of the bent-out surface portion. The rear side is the first side of the second layer, which originally pointed towards the first layer. The second surface component is the edge surface of the bent-out surface portion. The edge surface corresponds to the thickness of the second layer. The third surface component is the exposed surface of the first layer. The exposed surface is a surface of the second side of the first layer. The second side of the first layer originally points towards the second layer. The fourth surface component is again the thickness of the second layer, wherein this edge surface is not part of the bent-out surface portion, but part of the portion of the second layer remaining in the base surface.

The invention is based in a further secondary aspect on the idea of specifying a method of producing a heat spreading plate, wherein the heat spreading plate comprises a first layer and at least a second layer and at least one cooling fin. The heat spreading plate is preferably an aforementioned heat spreading plate according to the invention.

The method according to the invention is based on the fact that at least one weakening contour and/or a recess is introduced into a base surface of the second layer, which weakening contour or recess borders a surface portion at least in sections in such a way that the surface portion is connected by at least one connecting point to the base surface, wherein the surface portion is then bent out of the base surface.

The at least one weakening contour and/or the at least one recess is consequently to be introduced into the second layer, in particular into the base surface of the second layer, in such a way that no weakening contour and/or no recess is formed that enables a complete detachment of the surface portion from the second layer. The weakening contour and/or the recess has a shape which is such that at least one connecting point of the surface portion is connected to the base surface. In other words, the weakening contour and/or the recess is constituted such that a complete severing of the surface portion from the base surface of the second layer is made impossible.

The connecting point to the base surface is preferably the subsequent bending portion of the surface portion. As already mentioned, the bent-out surface portion can comprise a bending portion and a surface-enlarged portion.

After at least one weakening contour and/or at least one recess has or have been introduced into the base surface of the second layer, the surface portion is then bent out of the base surface.

Bending-out is understood to mean any mechanical procedure which forms a surface portion with a bending portion. The bending-out can accordingly also be pressing-out or drawing-out or folding-out or pushing-out. The effect of these mechanical possibilities for forming a bent-out surface portion is that the connecting point to the base surface forms a bending portion of the surface portion.

The weakening contour and/or the recess can be introduced into the base surface of the second layer by means of cutting, in particular laser cutting or water jet cutting, and/or by means of milling and/or by means of stamping.

The pattern or the geometry of the surface portion to be bent out is determined with the introduction of the weakening contour and/or the recess into the base surface of the second layer. The bending-out of the surface portion, which is at least partially severed from the base surface of the second layer on account of the formation of a weakening contour and/or a recess, can take place by means of an upper stamp, in particular by means of an upper stamp and a counter-stamp formed complementary to the upper stamp.

The bending-out of the surface portion by means of an upper stamp takes place for example by the fact that an upper stamp, with for example individual press-out studs, presses against the second layer. The press-out studs are arranged on the upper stamp preferably at the same distance from one another as the weakening contours and/or recesses formed in the second layer, insofar as a heat spreading plate with a plurality of cooling fins is being produced. The at least one press-out stud presses on the surface portion bordered by means of the weakening contour and/or the recess.

A counter-stamp formed complementary to the upper stamp preferably comprises at least one recess, preferably a plurality of recesses, into which the press-out stud(s) of the upper stamp can enter. With the aid of the wall of the lower stamp, the angle to be obtained at which the surface portion projects from the base surface can be defined. The bent-out surface portion can be arranged at an angle of 10°-90° to the base surface of the second layer. The wall of the counter-stamp can accordingly form an angle in sections which amounts to 90°-170°.

In an embodiment of the invention, the fashioning of a weakening contour and/or a recess and the bending-out of the surface portion can be carried out by progressive stamping.

The second layer can be connected to the first layer, in particular by soldering or diffusion annealing or sintering or eutectic bonding or low-temperature sintering or diffusion soldering or adhesive bonding. It is possible for the second layer to be connected to the first layer before the introduction of the weakening contour and/or the recess. Furthermore, it is possible for the connection of the first layer to the second layer to take place before the bending-out of the surface portion. For the bending-out of the surface portion, in the presence of a second layer connected to the first layer, it is necessary for the surface portion to be drawn out from the base surface of the second layer, in particular by means of a gripping device. Equally in the case of drawing-out, a bending portion is also formed at the connecting point of the surface portion with the base surface.

It is possible for a third layer made of a low-expansion material to be constituted between the first layer and the second layer. The low-expansion material can be a nickel alloy, in particular invar (Fe₆₅Ni₃₅) or invar 36 (Fe₆₄Ni₃₆) or kovar (Fe₅₄Ni₂₉Co₁₇), and/or tungsten (W) and/or an iron-nickel-cobalt alloy (FeNiCo alloy). The third layer is particularly preferably formed from molybdenum or a molybdenum alloy.

Insofar as a third layer is constituted between the first layer and the second layer, it is advantageous for the first layer, the second layer and the third layer to be connected together at a connecting temperature of 150° C.-300° C., in particular by a low-temperature sintering process.

In a further embodiment of the method according to the invention, it is possible for the second layer to remain lying on the counter-stamp or lower stamp after the bending-out of the at least one surface portion. The layers, which are to be connected, of the heat spreading plate to be produced are successively placed on the second layer. With the aid of a further upper stamp, which does not comprise any press-out studs, a pressure can be applied to all the layers to be connected. It is possible for the layers of the heat spreading plate to be materially connected together by means of connection layers, in particular by means of sintering paste using the process of pressure sintering. For this purpose, the upper stamp presses on the counter-stamp and therefore on the layers of the heat spreading plate located in between.

The invention is also based on the idea of specifying an electronic module with at least one electronic component and at least one heat spreading plate, wherein the heat spreading plate is an aforementioned heat spreading plate according to the invention or a heat spreading plate produced according to the invention.

The electronic module comprises at least one electronic component, which is connected indirectly or directly to a first side of the first layer, which is constituted facing away from the second layer. The first side of the first layer can also be referred to as the surface of the first layer. The heat generated by the electronic component acts in particular on the surface of the first layer or the first side of the first layer. In the case of an indirect connection of the at least one electronic component to the surface of the first layer, it is possible for a contacting layer, in particular a bonding layer or solder layer or sintering paste layer, to be constituted between the electronic component and the heat spreading plate.

The second layer of the heat spreading plate is preferably constituted as a component subjected to a cooling medium, in particular air and/or water and/or glycol and/or oil.

The at least one cooling fin of the heat spreading plate can be formed at an angle of 10°-90° to the flow direction of the cooling medium. In particular, it is possible for the cooling fin to be aligned parallel or perpendicular to the flow direction of the cooling medium. Depending on the application, the at least one cooling fin can have a preferred shape and/or alignment. The following examples of embodiment were able to be ascertained in investigations and hydrodynamic simulations:
Cooling medium air with a small mass flow:

The cooling fins preferably have a large cooling surface and are preferably formed square or rectangular; the incident flow on the cooling surfaces of the cooling fins is parallel to the flow direction of the cooling medium and the cooling surfaces of the cooling fins have large surface spacings from one another.
Cooling medium air with a large mass flow:

The cooling fins preferably have small cooling surfaces; the incident flow on the cooling surfaces of the cooling fins is preferably parallel to the flow direction of the cooling medium and the cooling surfaces of the cooling fins have small surface spacings from one another.
Cooling medium water (optionally with glycol) with a small mass flow with a low pressure loss:

The cooling fins have small cooling surfaces and are preferably constituted pin-shaped or semicircular; the incident flow on the cooling surfaces of the cooling fins is parallel up to angularly inclined to the flow direction of the cooling medium and the cooling surfaces of the cooling fins have average surface spacings from one another.
Cooling medium water (optionally with glycol) with a large mass flow and a high pressure loss:

The cooling fins have average cooling surfaces and are preferably constituted rectangular or semicircular; the incident flow on the cooling surfaces of the cooling fins is at a large angle or perpendicular to the flow direction of the cooling medium and the cooling surfaces of the cooling fins preferably have small surface spacings from one another.
Cooling medium oil with a small mass flow:

The cooling fins preferably have large cooling surfaces and are preferably constituted rectangular or semicircular; the incident flow on the cooling surfaces of the cooling fins is preferably parallel to the flow direction of the cooling medium and the cooling surfaces of the cooling fins preferably have large surface spacings from one another.
Cooling medium oil with a large mass flow and a high pressure loss:

The cooling fins have large cooling surfaces and are preferably constituted rectangular or semicircular; the incident flow on the cooling surfaces of the cooling fins is preferably at an angle to the flow direction of the cooling medium and the cooling surfaces of the cooling fins preferably have large surface spacings from one another.

The largest surface component of the cooling tin is preferably referred to as the cooling surface of a cooling fin. The cooling surface or the shape of the cooling surface is determined on the basis of the shape of the introduced recess and/or the shape of the introduced weakening contour.

The invention will be explained in greater detail below by reference to the appended schematic drawings on the basis of examples of embodiment. In these figures:

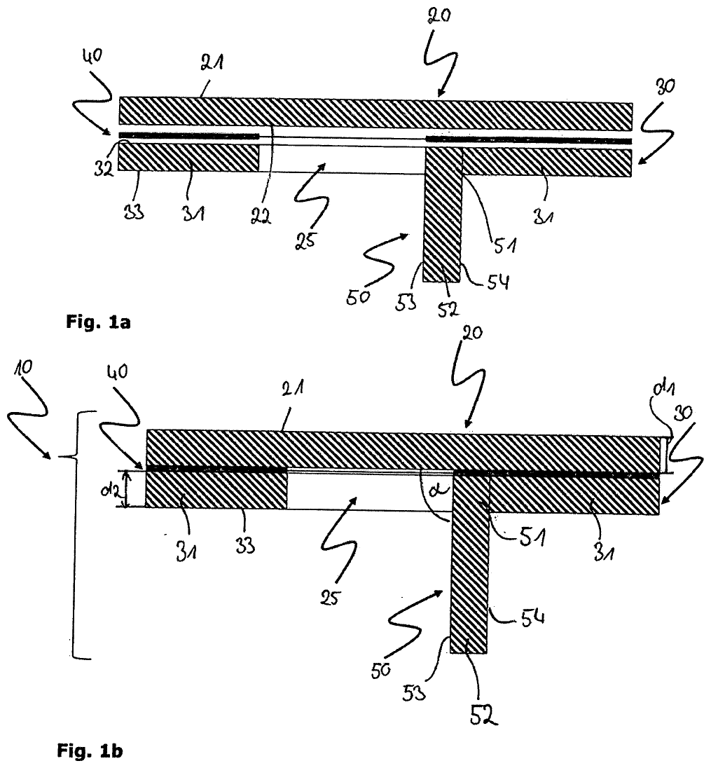

FIG. 1a shows the arrangement of individual layers and elements of a heat spreading plate with a cooling fin according to a first example of embodiment;

FIG. 1b shows a heat spreading plate with a cooling fin according to FIG. 1a in the connected state;

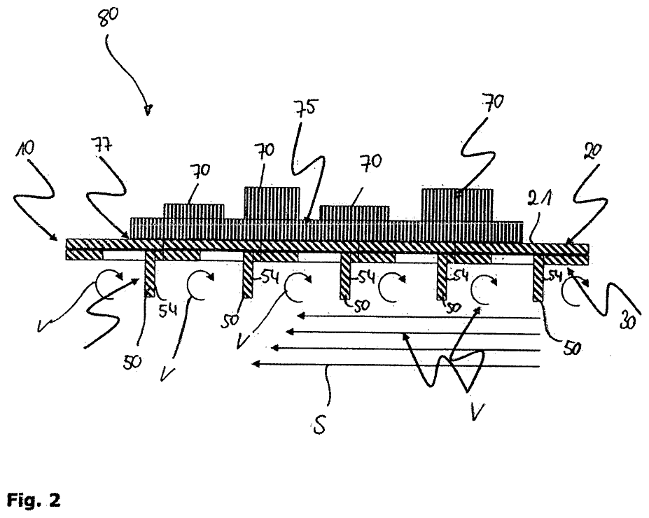

FIG. 2 shows a heat spreading plate with a plurality of cooling fins;

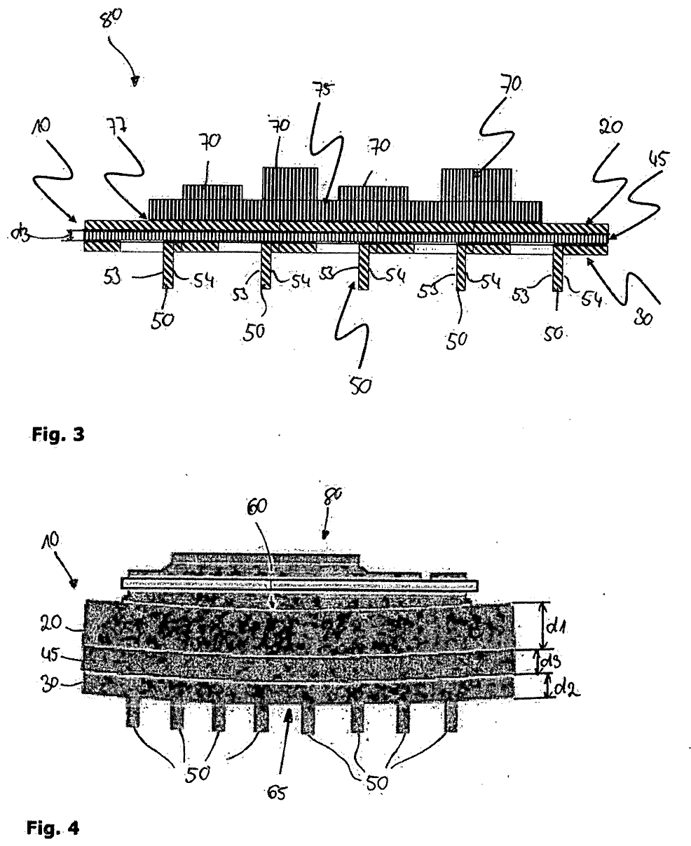

FIG. 3 shows a heat spreading plate with a plurality of cooling fins according to a further example of embodiment;

FIG. 4 shows an electronic module according to the invention with a concave formation of the heat spreading plate;

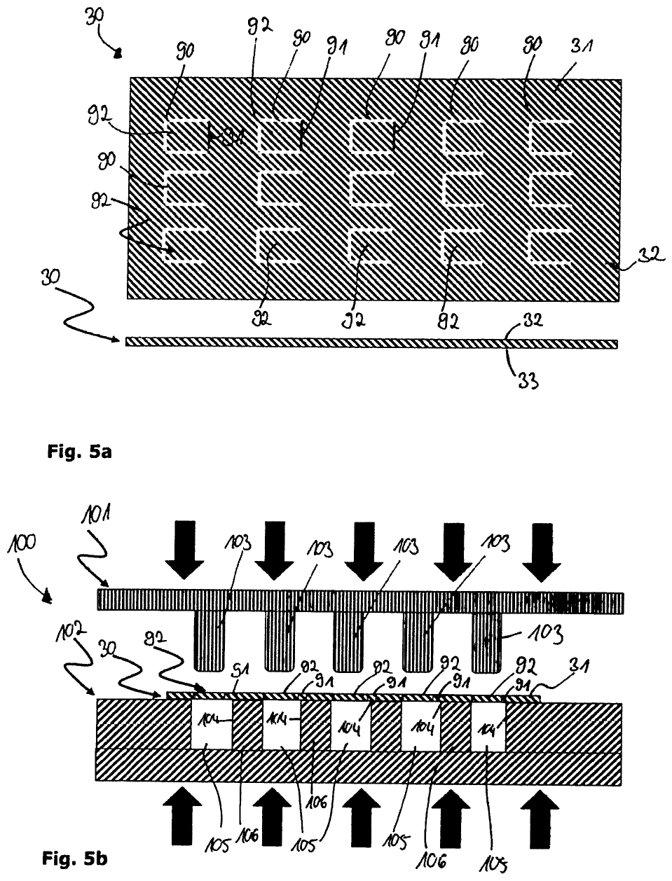

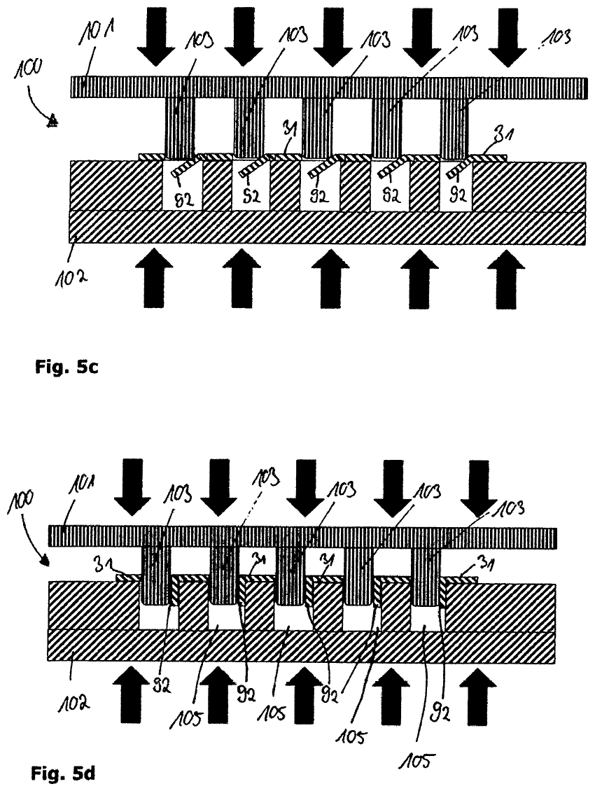

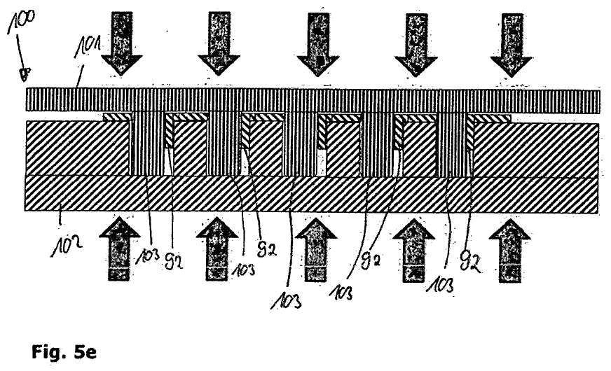

FIG. 5a-5e show individual process steps with regard to the bending-out of a surface portion; and

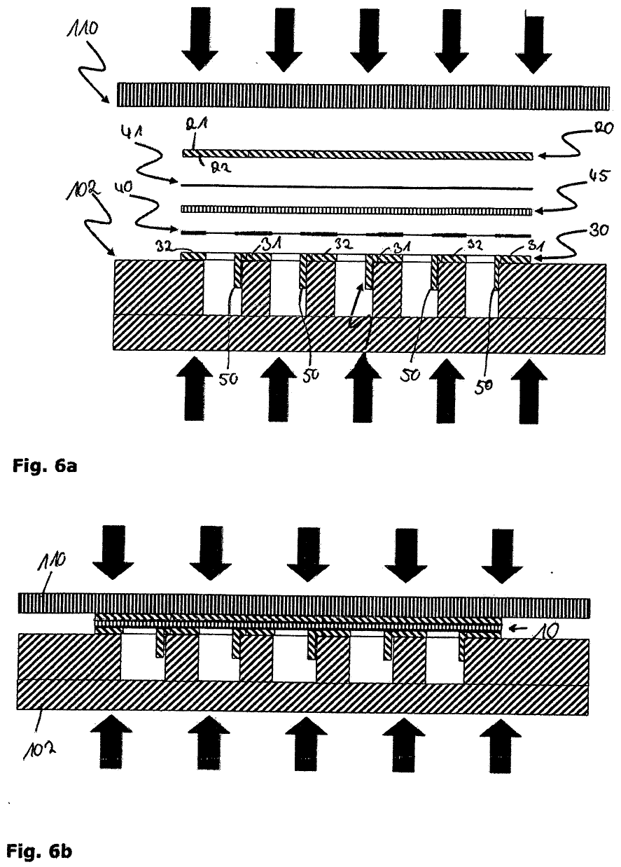

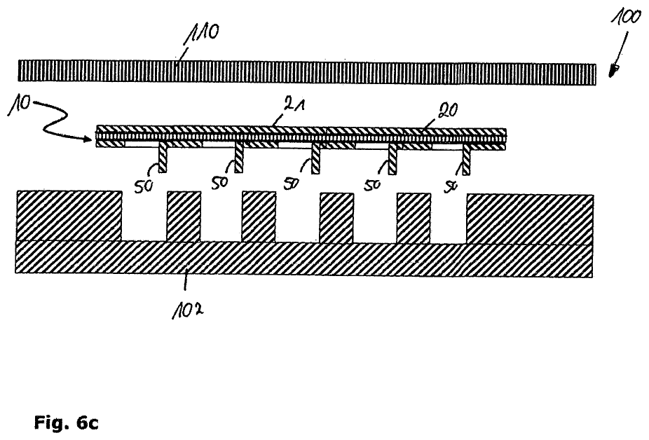

FIG. 6a-6c show individual process steps with regard to the connecting of the individual layers of the heat spreading plate.

Identical reference numbers are used below for identical and identically acting parts.

FIG. 1a represents the individual layers and surface portions of a heat spreading plate 10 to be produced (see FIG. 1b). Accordingly, first layer 20 and at least a second layer 30 are arranged one above the other. A connection layer 40 is constituted between first layer 20 and second layer 30. Second layer 30 comprises a base surface 31, which is essentially formed parallel to first layer 20. First layer 20 comprises a first side 21 and a second side 22. First side 21, which is constituted facing away from second layer 30, forms the surface of heat spreading plate 10 to be produced. Second side 22 of first layer 20 is facing towards second layer 30. Second layer 30 also comprises a first side 32, which is assigned to first layer 20. Second side 33 of second layer 30, on the other hand, is constituted facing away from first layer 20.

First layer 20 and second layer 30 are preferably produced from heat-conducting materials. These may be copper and/or a copper alloy and/or aluminium and/or an aluminium alloy and/or aluminium silicon carbide. Connection layer 40, which is constituted between first layer 20 and second layer 30, is preferably a sintered layer. This sintered layer can for example comprise silver particles.

A surface portion 50 is bent out from base surface 31 of second layer 30. This bent-out surface portion 50 forms the cooling fin. Bent-out surface portion 50 comprises a bending portion 51 and a surface-enlarging portion 52. Second layer 30 comprises a cutout 25 on account of bent-out surface portion 50. Access to second side 22 of first layer 20 can be created in the connected state of layers 20 and 30 (see FIG. 1b) on account of cutout 25. In the present case, connection layer 40 is not constituted in cutout 25. A sintering paste, which can form a connection layer 40, can be applied on first layer 20 or one second layer 30 for example with the aid of stencils, so that connection layer 40 can also comprise cutouts. Alternatively, it is possible for connection layer 40 to be constituted continuous, i.e. without cutouts.

In the present case, bent-out surface portion 50 is arranged at an angle α of 90° to base surface 31 of second layer 30. Angle α is formed between cooling surface 53 and second side 22 of first layer 20. In other words, angle α is formed in the region of cutout 25.

The whole surface of heat spreading plate 10 preferably comprises a galvanically applied nickel coating. The nickel coating is corrosion-inhibiting. If heat spreading plate 10 is used as a water cooler, the galvanic nickel coating prevents the formation of corrosion. The surface of heat spreading plate 10 is understood to mean both first side 21 of the first layer 20 and also second side 33 of second layer 30. The surface of heat spreading plate 10 also includes cooling surfaces 53 and 54 of bent-out surface portion 50. The portion of second side 22 of first layer 20 lying in cutout 25 also belongs to the surface. This also applies to visible thicknesses d1 and d2 of first layer 20 and of second layer 30.

Alternatively, it is possible that only second layer 30 or second side 33 of second layer 30 and the cooling fin 50 comprises or comprise a nickel coating. In addition, the exposed portions of second side 22 of first layer 20 can comprise a coating. These portions of the heat spreading plate in particular are subjected to water or a liquid in the state when in use.

FIG. 2 represents a heat spreading plate 10 with a plurality of bent-out surface portions 50 which form cooling fins. A plurality of electronic components 70 are arranged on first side 21 of first layer 20. These electronic components 70 are located on a substrate plate 75. Substrate plate 75 is applied, together with electronic components 70, on first side 21 of first layer 20, for example by means of a solder joint 77. A bonding connection or a sintered connection could also be constituted instead of solder joint 77. Heat spreading plate 10 with cooling fins 50 and the electronic subassembly, which is formed by substrate plate 75 and electronic components 70, thus form an electronic module 80. Second layer 30 of heat spreading plate 10 is constituted as a component exposed to a cooling medium. The cooling medium can for example be air or a liquid.

The arrows constituted parallel to one another indicate flow direction S of the cooling medium. Cooling fins 50 are constituted perpendicular to flow direction S of the cooling medium. The incident flow of the cooling medium on cooling surfaces 54 of cooling fins 50 is therefore at right angles. On account of the incident flow on cooling surfaces 54 being at right angles, turbulence occurs between cooling fins 50, so that a particularly good cooling capacity is present here.

FIG. 3 represents a further embodiment of on an electronic module 80. Represented heat spreading plate 10 comprises a first layer 20, a second layer 30 and a third layer 45. This third layer 45 is a low-expansion layer. The low-expansion material can be a nickel alloy, in particular invar (Fe₆₅Ni₃₅) or invar 36 (Fe₆₄Ni₃₆) or kovar (Fe₅₄Ni₂₉Co₁₇), and/or tungsten (W) and/or an iron-nickel-cobalt alloy (FeNiCo alloy). Molybdenum (Mo) or a molybdenum alloy has proved to be a particularly preferred material with regard to the low-expansion material of third layer 45. Third layer 45 can therefore be made of molybdenum or a molybdenum alloy or can comprise molybdenum or a molybdenum alloy. This low-expansion third layer 45 or this third layer 45 made of a low-expansion material produces a reduction in expansion with rising temperature and in this way reduces the expansion difference with respect to the materials of electronic components 70 and/or substrate plate 75. Stress-induced cracks are thus prevented from arising in the jointing zone between heat spreading plate 10 and substrate plate 75 and the heat flow is prevented from being significantly reduced on account of the cracks. This is typically the case with ceramic-based substrate plates, which have an average thermal expansion of 4-8 ppm/K. Third low-expansion layer 45 is made for example of molybdenum.

FIG. 4 represents a further heat spreading plate 10 with cooling fins 50. The layer structure of heat spreading plate 10 is asymmetrical. That means that thickness d1 of first layer 20 is greater than thickness d2 of second layer 30 and greater than thickness d3 of third layer 45. Third layer 45 is a low-expansion layer. On account of the asymmetrical formation, heat spreading plate 10 has a concave shape. The concave shape forms a depression 60 and an arched side 65.

FIGS. 5a-5e represent in steps how bent-out surface portion 50 of second layer 30 can be produced. FIG. 5a shows second layer 30 in a plan view onto first side 32. With regard to the orientation of first side 32 and second side 33, reference should be made to the previous explanations in connection with FIGS. 1a and 1b.

A plurality of recesses 90 are introduced into second layer 30. Overall, three horizontal rows and five vertical columns with a total of 15 recesses 90 are formed. Recesses 90 are constituted U-shaped. It is also conceivable for recesses 90 to the constituted V-shaped or semicircular. The spacings in the horizontal direction between recesses 90 lying in a line are identical. The spacings between recesses 90 next to one another in the horizontal direction are identical.

Recesses 90 are introduced into second layer 30, for example by cutting, in particular by laser cutting or water-jet cutting. It is also possible for recesses 90 to be introduced into second layer 30 by punching or milling. Recesses 90 border surface portions 92, wherein these surface portions 92 are the bent-out surface portions. In the not yet bent-out state, all surface portions 92 are in the same plane as base surface 31 of second layer 30. Each surface portion 92 is connected to base surface 31 at at least one connecting point 91. In other words, recess 90 should be introduced into base surface 31 in such a way that surface portion 92 cannot be completely severed from base surface 31. Connecting point 91 forms subsequent bending portion 51. The contour or the geometry of subsequently bent-out surface portion 50 is determined by the shape of recess 90.

After recesses 90 have been introduced into second layer 30, surface portions 92 are pressed out of base surface 31. For this purpose, second layer 30 is placed into a stamping device 100. Stamping device 100 comprises an upper stamp 101 and a counter-stamp 102. Upper stamp 101 comprises press-out studs 103. Upper stamp 101 preferably comprises as many press-out studs 103 as there are pressed-out surface portions 50 to be produced. Second layer 30 is positioned in stamping device 100 in such a way that press-out studs 103 can press on surface portions 92. Connecting points 91 preferably lie adjacent to the edges of walls 104 of counter-stamp 102. Counter-stamp 102 comprises recesses 105, into which press-out studs 103 can slide.

As is represented in FIG. 5e, surface portions 92 are pushed out or bent out of base surface 31 due to the pressures of upper stamp 101 and counter-stamp 102, said pressures prevailing in the arrow direction. Base surface 31 remains lying on anvil-like counter-element 106 (see FIG. 5c) of counter-stamp 102.

As represented in FIG. 5d, recesses 105 are wider than press-out studs 103, so that surface portions 92 can be pressed downwards vertically along wall 104.

As is represented in FIG. 5e, upper stamp 101 is pressed into counter-stamp 102 in such a way that surface portion 92 is bent at 90° to base surface 31. In this state, a completely bent-out surface portion 50 is present. The shape of walls 104 (see FIG. 5b) determines subsequent angle α. Subsequent bending portions 51 are formed in each case at an edge of a wall 104.

FIGS. 6a to 6c represent, by way of example, how second layer 30 can be connected to the other layers of heat spreading plate 10 to be produced. For this purpose, upper stamp 101 with press-out studs 103 is moved away. Second layer 30 remains with bent-out surface portions 50 in the counter-stamp (see FIG. 6a). A connection layer 40 can next be applied on first side 32 of second layer 30. This connection layer 40 can for example be a bonding layer or a sintered layer or a solder layer. Connection layer 40 is preferably applied only one base surface 31 of first side 32. Third layer 45 made of a low-expansion material is preferably applied on connection layer 40. Third layer 45 can for example be a molybdenum layer. A connection layer 41 can in turn be applied on third layer 45. Here too, it can be a bonding layer or a sintered layer or a solder layer. First layer 20 is then arranged. Second side 22 of first layer 20 points in the direction of second layer 30.

The arrangement of individual layers 20, 30, 40, 41 and 45, as represented in FIG. 6b, is pressed with the aid of an upper stamp 110 and a counter-stamp 102. For example, this can take place as part of a low-pressure temperature sintering process. Here, a heat application at temperatures of 150° C.-300° C. takes place. A durable sintering connection is created by the application of pressures, which amount to between 5 MPa and 30 MPa, in particular 25 MPa, at a temperature of 250° C. for a duration of preferably 1 to 10 min, for example 4 min.

As represented in FIG. 6c, the removal of upper stamp 110 then takes place, so that heat spreading plate 10 can be removed from stamping device 100.

Finally, heat spreading plate 10 can be provided completely with a corrosion-inhibiting coating. For example, a nickel coating can be applied on the entire surface of heat spreading plate 10.

1-16. (canceled)

17. A heat spreading plate comprising:
at least one cooling fin;
at least a first layer; and
at least a second layer;
wherein at least one surface portion that is bent out from a base surface of the second layer forms a cooling fin.

18. The heat spreading plate of claim 17, wherein one of the first layer and the second layer is formed from a group comprising copper, a copper alloy, aluminium, an aluminium alloy, and aluminium silicon carbide (AlSiC).

19. The heat spreading plate of claim 17, wherein a connection layer comprising one of a group comprising a sintered layer, bonding layer, and solder layer is constituted between the first layer and the second layer.

20. The heat spreading plate of claim 17, wherein at least a third layer made of a low-expansion material comprising at least one of a group comprising a nickel alloy, invar (Fe₆₅Ni₃₅), invar 36 (Fe₆₄Ni₃₆), kovar (Fe₅₄Ni₂₉Co₁₇), tungsten (W), an iron-nickel-cobalt alloy (FeNiCo alloy), molybdenum (Mo) is constituted between the first layer and the second layer.

21. The heat spreading plate of claim 17, wherein the at least one cooling fin is constituted one of pin-shaped, rectangular, semicircular, and square.

22. The heat spreading plate of claim 17, wherein the bent-out surface portion is arranged at an angle of 10°-90° to the base surface of the second layer.

23. The heat spreading plate of claim 17, wherein a corrosion-inhibiting coating constituted at least in sections a galvanic nickel coating of the surface of the heat spreading plate.

24. A method for producing a heat spreading plate with at least a first layer and a second layer and at least one cooling fin, wherein at least one surface portion that is bent out from a base surface of the second layer forms a cooling fin, the method comprising:
introducing at least one weakening contour or a recess into a base surface of the second layer, which weakening contour or recess borders a surface portion at least in sections in such a way that the surface portion is connected by at least one connecting point to the base surface, wherein the surface portion is then bent out of the base surface.

25. The method according to claim 24, wherein the weakening contour or the recess is introduced into the base surface of the second layer by means of cutting, in particular laser cutting or water jet cutting, and/or by means of milling and/or by means of stamping.

26. The method of claim 24, wherein the bending-out of the surface portion takes place by means of an upper stamp, in particular by means of an upper stamp and a counter-stamp formed complementary thereto.

27. The method of claim 24, wherein the second layer is connected to the first layer, in particular by soldering or diffusion annealing or sintering or eutectic bonding or low-temperature sintering or diffusion soldering or adhesive bonding.

28. The method of claim 24, wherein a third layer made of a low-expansion material, in particular of a nickel alloy, in particular invar (Fe₆₅Ni₃₅) or invar 36 (Fe₆₄Ni₃₆) or kovar (Fe₅₄Ni₂₉Co₁₇), and/or tungsten (W) and/or an iron-nickel-cobalt alloy (FeNiCo alloy), particularly preferably molybdenum (Mo), is constituted between the first layer and the second layer.

29. The method of claim 28, wherein the first layer, the second layer and the third layer are connected together at a connecting temperature of 150° C.-300° C., in particular by a low-temperature sintering process.

30. An electronic module with at least one electronic component and with at least one heat spreading plate comprising at least one cooling fin, at least a first layer and at least a second layer, and wherein at least one surface portion that is bent out from a base surface of the second layer forms a cooling fin,
wherein the at least one electronic component is connected indirectly or directly to a side of the first layer, which is constituted facing away from the second layer.

31. The electronic module of claim 30, wherein the second layer of the heat spreading plate is constituted as a component subjected to a cooling medium, comprising one of a group comprising air, water, glycol, and oil.

32. The electronic module of claim 31, wherein the at least one cooling fin is formed at an angle of 10°-90°, and one of perpendicular and parallel, to the flow direction of the cooling medium.
